(19) United States
(12) Patent Application Publication
(10) Pub. No.: US 2025/0338528 A1
(43) Pub. Date: Oct. 30, 2025

(54) HIGH ELECTRON MOBILITY TRANSISTOR DEVICE AND METHOD FOR MANUFACTURING THE SAME

(71) Applicant: XIAMEN SAN'AN INTEGRATED CIRCUIT CO., LTD., Xiamen (CN)

(72) Inventors: Hui ZHANG, Xiamen (CN); Shenghou LIU, Xiamen (CN); Jiebin ZHONG, Xiamen (CN); Xiguo SUN, Xiamen (CN)

(21) Appl. No.: 18/902,390

(22) Filed: Sep. 30, 2024

Related U.S. Application Data
(63) Continuation-in-part of application No. PCT/CN2024/090779, filed on Apr. 30, 2024.

(51) Int. Cl. H01L 29/66; H01L 29/20; H01L 29/423; H01L 29/45; H01L 29/778

(52) U.S. Cl. CPC H10D 30/015; H10D 30/475; H10D 62/85; H10D 62/8503; H10D 64/513; H10D 64/62

(57) ABSTRACT

A method for manufacturing an HEMT device includes providing a substrate; forming an epitaxial structure on the substrate; forming a passivation dielectric layer on the epitaxial structure; implanting ions to form an ion implantation region; forming a trench in the ion implantation region, the trench extending into the epitaxial structure, an area of a bottom surface of the trench being greater than that of a projection of the bottom surface of the trench on the substrate, an area of a projection of the ion implantation region on the substrate being greater than that of the bottom surface of the trench on the substrate; and depositing a metal layer in the trench to form an ohmic contact. An HEMT device includes a substrate, an epitaxial structure, a passivation dielectric layer, an ion implantation region, a trench, and a metal layer.

### CROSS-REFERENCE TO RELATED APPLICATION

This application is a continuation-in-part (CIP) of International Application No. PCT/CN2024/090779, filed on Apr. 30, 2024, the entire disclosure of which is incorporated by reference herein.

### FIELD

The disclosure relates to semiconductor manufacturing, and more particularly to a high electron mobility transistor device and a method for manufacturing the same.

### BACKGROUND

High electron mobility transistors (HEMTs) have the advantages of being capable of operating at high frequency, high voltage, high temperature, etc., and are the future of solid-state microwave power devices and power electronics. The performance of ohmic contact is important to the performance of HEMT devices. Reduction of ohmic contact resistance of a HEMT device may improve the performance of the HEMT device. GaN materials in the HEMT device have high stability and are not prone to chemical reactions, so they do not form ohmic bases easily.

Therefore, providing an HEMT device having a low ohmic contact resistance is a current technical problem to be resolved.

### SUMMARY

Therefore, an object of the disclosure is to provide a method for manufacturing a high electron mobility transistor (HEMT) device and an HEMT device that can alleviate at least one of the drawbacks of the prior art.

According to a first aspect of the disclosure, the method for manufacturing the HEMT device includes steps of:
providing a substrate;
forming an epitaxial structure on the substrate;
forming a passivation dielectric layer on the epitaxial structure;
implanting ions in a direction from a top surface of the epitaxial structure to the substrate so as to form an ion implantation region;
forming a trench in the ion implantation region, the trench at least extending into the epitaxial structure, an area of a bottom surface of the trench being greater than an area of a projection of the bottom surface of the trench on the substrate, an area of a projection of the ion implantation region on the substrate being greater than the area of the projection of the bottom surface of the trench on the substrate; and
depositing a metal layer in the trench so as to form an ohmic contact.

According to a second aspect of the disclosure, the HEMT device includes a substrate, an epitaxial structure, a passivation dielectric layer, an ion implantation region, a trench, and a metal layer. The epitaxial structure is disposed on the substrate. The passivation dielectric layer is disposed on the epitaxial structure. The ion implantation region extends in a direction from a top surface of the epitaxial structure to the substrate. The trench is located in the ion implantation region, and extends in the direction to reach at least a portion of the epitaxial structure. An area of a bottom surface of the trench is greater than an area of a projection of the bottom surface of the trench on the substrate. An area of a projection of the ion implantation region on the substrate is greater than the area of the projection of the bottom surface of the trench on the substrate. The metal layer is disposed in the trench so as to form an ohmic contact.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a flow chart of a method for manufacturing a high electron mobility transistor (HEMT) device according to an embodiment of the disclosure.

FIG. 2 are schematic views illustrating steps S10 to S40 of FIG. 1 according to the embodiment of the disclosure.

FIG. 3 is a schematic view of a partial structure of the HEMT device according to the embodiment of the disclosure.

FIGS. 4 to 6 are schematic views illustrating steps S50 to S70 of FIG. 1 according to various embodiments of the disclosure.

FIGS. 7 to 9 are schematic views of the HEMT device according to various embodiments of the disclosure.

FIG. 10 is a schematic top view of a partial structure of the HEMT device according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Currently, a source ohmic contact and a drain ohmic contact of a GaN-based HEMT device are usually formed by a high-temperature alloy process, an ion implantation process, or a secondary epitaxy process so as to achieve a low source ohmic contact resistance and a low drain ohmic contact resistance.

However, the high-temperature alloy process involves a metal layer at high temperature being rapidly annealed so as to form an electrode. The electrode usually has defects such as having a rough surface and uneven edges, and so is prone to electrical breakdown, reduced reliability, etc. In the ion implantation process, due to a peak concentration of ions being not on a surface of the metal layer, forming the electrode on the metal layer may not achieve a minimum ohmic contact resistance. In an etching process, due to difficulty in controlling an etching depth, the ohmic contact resistance may not be at a minimum. The secondary epitaxy process for preparing a highly doped GaN layer is complicated, difficult, and expensive, and therefore is not practical for mass producing large sized wafers.

Therefore, this disclosure provides an HEMT device and a method for manufacturing the same that may ensure performance of the HEMT device, reduce the ohmic contact resistance, and improve electrical properties of the HEMT device.

According to a first aspect of the disclosure, the method for manufacturing the HEMT device includes the following steps:
providing a substrate 10;
forming an epitaxial structure 20 on the substrate 10, the epitaxial structure 20 including a heterojunction interface that is formed between a GaN (gallium nitride) layer and a barrier layer 22 for generating a two-dimensional electron gas through polarization;
forming a passivation dielectric layer 30 on the epitaxial structure 20;
implanting ions in a direction (Z) from a top surface of the epitaxial structure 20 to the substrate 10 so as to form ion implantation regions 20a;
forming trenches 53 respectively in the ion implantation regions 20a, each of the trenches 53 at least extending into the epitaxial structure 20, an area of a bottom surface 53a of each of the trenches 53 being greater than an area of a projection of the bottom surface 53a of the each of the trenches 53 on the substrate 10, an area of a projection of each of the ion implantation regions 20a on the substrate 10 being greater than the area of the projection of the bottom surface 53a of a respective one of the trenches 53 on the substrate 10; and
depositing metal layers each of which is in a respective one of the trenches 53 so as to form an ohmic contact.

By virtue of the abovementioned method, an area of ohmic contact may be greatly improved, a contact between each of the metal layers and a high concentration region of ions in a respective one of the ion implantation regions 20a is ensured, an ohmic contact resistance between each of the metal layers and the epitaxial structure 20 is reduced, a requirement of etching precision is lowered, a level of etching difficulty is also lowered, thereby improving the electrical properties of the HEMT device.

In an embodiment, forming the trenches 53 includes:
forming a photoresist layer 40 on the passivation dielectric layer 30, and patterning the photoresist layer 40 to form first preformed trenches 51 located respectively above the ion implantation regions 20a;
etching the passivation dielectric layer 30 below the first preformed trenches 51 to form a second preformed trenches 52; and
etching the epitaxial structure 20 below the second preformed trenches 52 to form the trenches 53.

In an embodiment, a difference between a maximum depth and a minimum depth of each of the first preformed trenches 51 is represented by h1 that ranges from 44 nm to 225 nm, thereby avoiding adverse impacts on the subsequent manufacturing of the second preformed trenches 52 and the trenches 53 caused by the h1 being too great or too small.

In an embodiment, the photoresist layer 40 has a thickness represented by H, and h1 and H satisfy an equation of H≥5×h1, thereby ensuring that the photoresist layer 40 has enough thickness to be patterned.

In an embodiment, a difference between a maximum depth and a minimum depth of each of the second preformed trenches 52 is represented by h2, and h1 and h2 satisfy an equation of h2=h1/A, where A is a value of an etch selectivity ratio of the passivation dielectric layer 30 to the photoresist layer 40 and ranges from 2.5 to 4.

In an embodiment, a difference between a maximum depth and a minimum depth of each of the trenches 53 is represented by h3, and h1 and h3 satisfy an equation of h3=h1÷(A×B), where A is the value of the etch selectivity ratio of the passivation dielectric layer 30 to the photoresist layer 40 and ranges from 2.5 to 4, and B is a value of an etch selectivity ratio of the passivation dielectric layer 30 to the epitaxial structure 20 and ranges from 1.2 to 2.

In an embodiment, the difference between a maximum depth and a minimum depth of each of the trenches 53 is represented by h3 that ranges from 10 nm to 50 nm. For example, h3 may be 10 nm, 15 nm, 20 nm, 30 nm, 40 nm, or 50 nm, thereby ensuring a contact between each of the metal layers (formed on the bottom surfaces 53a of the trench 53) and the high concentration region of ions in the respective ion implantation region 20a. A width of the bottom surface 53a of each of the trenches 53 in a horizontal direction (X), which is perpendicular to the direction (Z), is represented by W that ranges from 10 μm to 50 μm.

In an embodiment, the epitaxial structure 20 at least includes the GaN (gallium nitride) layer 21 that is disposed on the substrate 10 to serve as a channel layer and the barrier layer 22 that is disposed on the GaN layer 21. Each of the trenches 53 is formed by etching the epitaxial structure 20 until the GaN layer 21 is exposed. By virtue of the abovementioned method, an ohmic contact among the GaN layer 21 and the barrier layer 22, each of the metal layers (respectively disposed in the trenches 53), is formed, thereby ensuring the electrical properties of the HEMT device.

In an embodiment, an ion concentration of each of the ion implantation regions 20a first increases and then decreases in the direction (Z) from the top surface of the epitaxial structure 20 to the substrate 10. Each of the ion implantation regions 20a has a high concentration region, and an ion concentration in the high concentration region exceeds a predetermined value. Each of the trenches 53 extends into the high concentration region of the respective ion implantation region 20a. The predetermined value in each of the ion implantation regions 20a is no smaller than 80% of a concentration peak value of the ions in the each of the ion implantation regions 20a. By virtue of the abovementioned method, each of the metal layers disposed in the respective trench 53 may contact the high concentration region, thereby reducing the ohmic contact resistance.

In an embodiment, when implanting the ions into the ion implantation regions 20a, implantation energy goes from high to low.

In an embodiment, the bottom surface 53a of each of the trenches 53, a bottom surface 51a of each of the first preformed trenches 51, and a bottom surface 52a of each of the second preformed trenches 52 are each an inclined flat surface, a curved surface, a concave surface, a convex surface, or combinations thereof, and may be designed according to actual requirements and are not limited thereto.

In an embodiment, when the bottom surface 53a of each of the trenches 53 is the inclined flat surface, the bottom surface 53a forms an angle (a) with an imaginary plane that is parallel to the substrate 10, and the angle (a) ranges from 5° to 10°. When the angle (a) ranges from 5° to 10°, the inclined flat surface is formed to expose the high concentration region of ions in the respective ion implantation region 20a, so as to reduce the ohmic contact resistance between each of the metal layers and the respective ion implantation region 20a.

In an embodiment, the method for manufacturing the HEMT device further includes the following steps. A gate electrode 63 is formed on the passivation dielectric layer 30. The gate electrode 63 is in electrical contact with the epitaxial structure 20 through a through hole of the passivation dielectric layer 30. A passivation protection layer 70 is disposed on the passivation dielectric layer 30.

According to a second aspect of the disclosure, the HEMT device is provided and includes a substrate 10, an epitaxial structure 20, ion implantation regions 20a, trenches 53, and metal layers.

The epitaxial structure 20 is disposed on the substrate 10. The passivation dielectric layer 30 is disposed on the epitaxial structure 20. Each of the ion implantation regions 20a extends in a direction (Z) from a top surface of the epitaxial structure 20 to the substrate 10. The trenches 53 are respectively located in the ion implantation regions 20a, and each extends in the direction (Z) to reach at least a portion of the epitaxial structure 20. An area of a bottom surface 53a of each of the trenches 53 is greater than an area of a projection of the bottom surface 53a of the each of the trenches 53 on the substrate 10, and an area of a projection of each of the ion implantation regions 20a on the substrate 10 is greater than the area of the projection of the bottom surface 53a of a respective one of the trenches 53 on the substrate 10. Each of the metal layers is disposed in a respective one of the trenches 53 so as to form an ohmic contact.

In an embodiment, the epitaxial structure 20 at least includes a GaN layer 21 that is disposed on the substrate 10 and a barrier layer 22 that is disposed on the GaN layer 21. Each of the trenches 53 extends in the direction (Z) to reach the GaN layer 21.

Each of the ion implantation regions 20a has a high concentration region. An ion concentration in the high concentration region exceeds a predetermined value, and the predetermined value in each of the ion implantation regions 20a is no smaller than 80% of a concentration peak value of ions in the each of the ion implantation regions 20a. The bottom surface 53a of each of the trenches 53 is formed in the high concentration region of a respective one of the ion implantation regions 20a.

In an embodiment, a difference between a maximum depth and a minimum depth of each of the trenches 53 is represented by h3 that ranges from 10 nm to 50 nm. A width of the bottom surface 53a of each of the trenches 53 in a horizontal direction (X) is represented by W that ranges from 10 μm to 50 μm.

In an embodiment, the bottom surface 53a of each of the trenches 53 is an inclined flat surface, a curved surface, a concave surface, a convex surface, or combinations thereof.

In an embodiment, when the bottom surface 53a of each of the trenches 53 is the inclined flat surface, the bottom surface 53a forms an angle (a) with an imaginary plane that is parallel to the substrate 10, and the angle (a) ranges from 5° to 10°.

In an embodiment, the HEMT device further includes a gate electrode 63 and a passivation protection layer 70. The gate electrode 63 is formed on the passivation dielectric layer 30, and is in electrical contact with the epitaxial structure 20 through a through hole of the passivation dielectric layer 30. The passivation protection layer 70 is disposed on the passivation dielectric layer 30.

The technical solutions of the present disclosure are next described and illustrated in detail by means of a variety of specific embodiments in conjunction with different embodiments and the accompanying drawings of the specification.

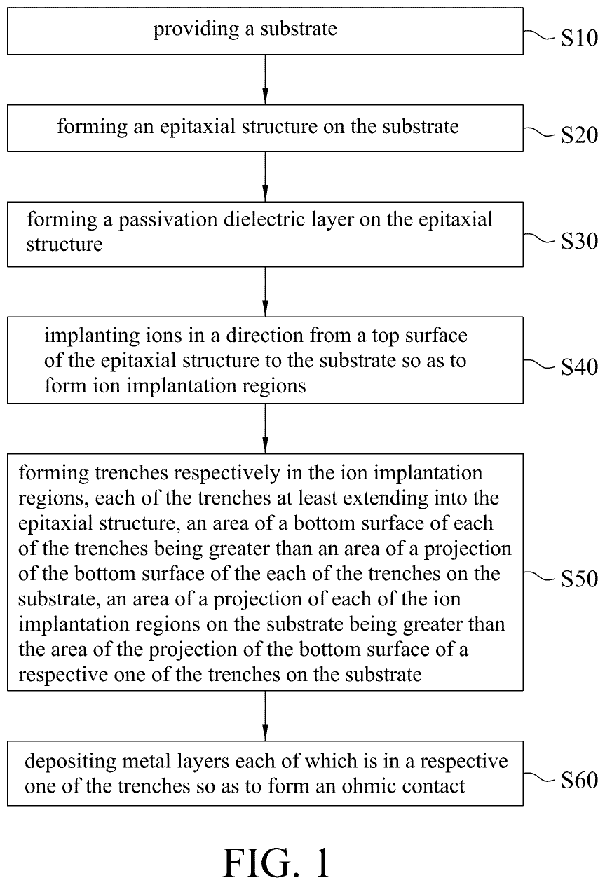

Referring to FIGS. 1 to 3, FIG. 1 is a flow chart illustrating a method for manufacturing an HEMT device according to the disclosure.

In step S10, a substrate 10 is provided. The substrate 10 may be a substrate known to those skilled in the art adapted for disposing semiconductor integrated circuit elements thereon. The substrate 10 may be a heterogeneous substrate, and common materials thereof include silicon, silicon carbide, sapphire, gallium nitride, and the like, but are not limited thereto.

In step S20, an epitaxial structure 20 is formed on the substrate 10 by suitable processes such as chemical vapor deposition, physical vapor deposition, or atomic layer deposition, but is not limited thereto. Specifically, referring to FIG. 3, the epitaxial structure 20 at least includes a GaN layer 21 and a barrier layer 22. A heterojunction interface is formed between the GaN layer 21 and the barrier layer 22 for generating a two-dimensional electron gas. The barrier layer 22 may be a single layered structure or a multilayered structure made of aluminum gallium nitride (AlGaN), aluminum nitride (AlN), aluminum indium nitride (AlInN), indium gallium nitride (InGaN), or aluminum indium gallium nitride (AlInGaN). A thickness of the barrier layer 22 ranges from 10 nm to 30 nm.

It should be mentioned that, according to actual requirements, the epitaxial structure 20 may further include a nucleation layer, a transition layer, a buffer layer, an insertion layer, or combinations thereof (not shown in the figures), and is not limited thereto.

For example, an AlN (aluminum nitride) insertion layer may be disposed between the GaN layer 21 and the barrier layer 22. A thickness of the AlN insertion layer may range from 0.5 nm to 2 nm. The AlN insertion layer may improve channel electron density, electron mobility, and the heterogeneous interface quality.

For example, the nucleation layer and the buffer layer may be disposed between the substrate 10 and the GaN layer 21. The nucleation layer is made of AlN and has a thickness ranging from 10 nm to 50 nm. The nucleation layer may release stress generated by a lattice mismatch between the buffer layer and the substrate 10 and thermal stress generated by thermal expansion, and optimize evenness of a surface of the nucleation layer, thereby reducing defects of epitaxial growth. The buffer layer may be made of AlN, AlGaN, GaN, or combinations thereof to alleviate a lattice mismatch and a thermal expansion coefficient mismatch between the substrate 10 and the GaN layer 21. In some embodiments, the buffer layer is made of GaN.

In step S30, a passivation dielectric layer 30 is formed on the epitaxial structure 20. The passivation dielectric layer 30 may be made of silicon oxide (SiO₂), silicon nitride (SiN), aluminum oxide (Al₂O₃), silicon oxynitride (SiON), or combinations thereof, and is not limited thereto. By virtue of such design of the passivation dielectric layer 30, external charged particles or impurities may be effectively prevented from affecting the normal operation of the HEMT device.

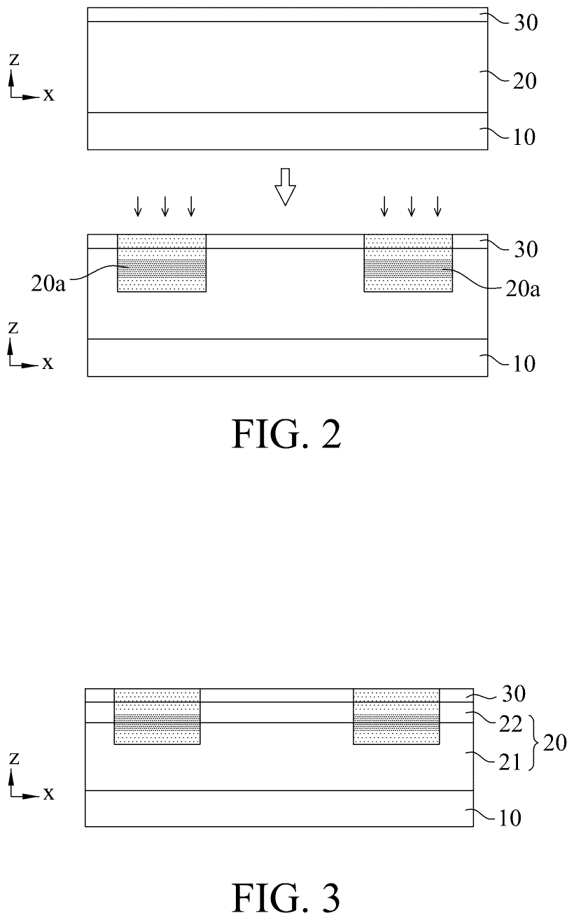

Referring to FIGS. 2 and 3, in step S40, the ions are implanted in a direction (Z) from a top surface of the epitaxial structure 20 to the substrate 10 so as to form ion implantation regions 20a. The ion implantation regions 20a are formed in the epitaxial structure 20 respectively under metal layers each of which is to be formed into an ohmic contact. In this embodiment, the HEMT device includes a source electrode 61 and a drain electrode 62 which respectively serve as the metal layers. The ion implantation regions 20a includes a source ion implantation region and a drain ion implantation region. An upper area of the source ion implantation region forms an ohmic contact having low resistance with the source electrode 61, and an upper area of the drain ion implantation region forms an ohmic contact having low resistance with the drain electrode 62. The ions that are implanted may be silicon ions. The ions may be implanted perpendicularly onto the top surface of the epitaxial structure 20, or at an angle according to actual requirements and are not limited thereto. It should be noted here that the top surface of the epitaxial structure 20 is a surface of the epitaxial structure 20 away from the substrate 10.

In some embodiments, when implanting the ions to form the ion implantation regions 20a, implantation energy goes from high to low. That is to say, a high energy is used first to implant the ions, followed by a low energy to implant the ions for multiple implantations. In some embodiments, in a case where the ions are implanted twice, an energy used to implant the ions in the first time is greater than an energy used to implant the ions in the second time. In some embodiments, the energy used to implant the ions in the first time ranges from 60 Kev to 75 Kev, and the energy used to implant the ions in the second time ranges from 35 Kev to 50 Kev. Specifically, the high energy used to implant the ions allows a concentration of the ions to be greater and a distribution of the ions to be deeper. In order to prevent the ions that implanted by the high energy from being blocked by the ions implanted by the low energy, the high energy is used first so as to achieve a predetermined depth of implantation for the ion implantation regions 20a.

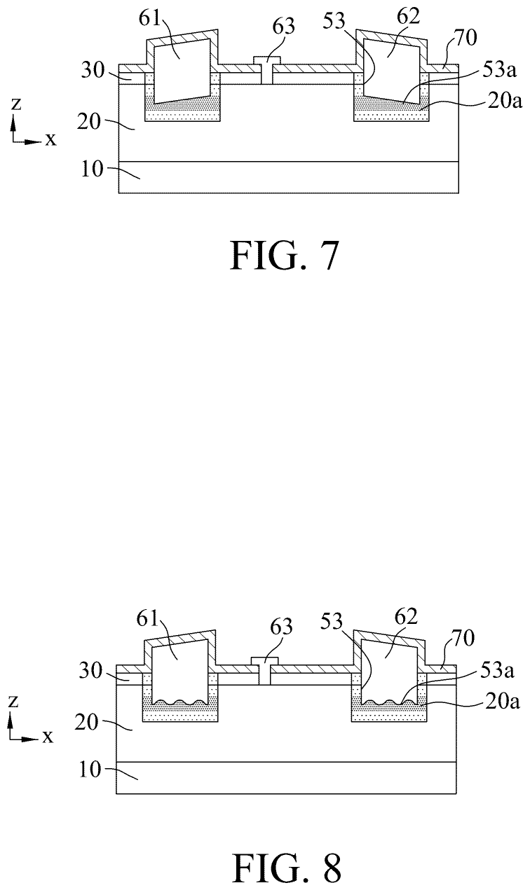

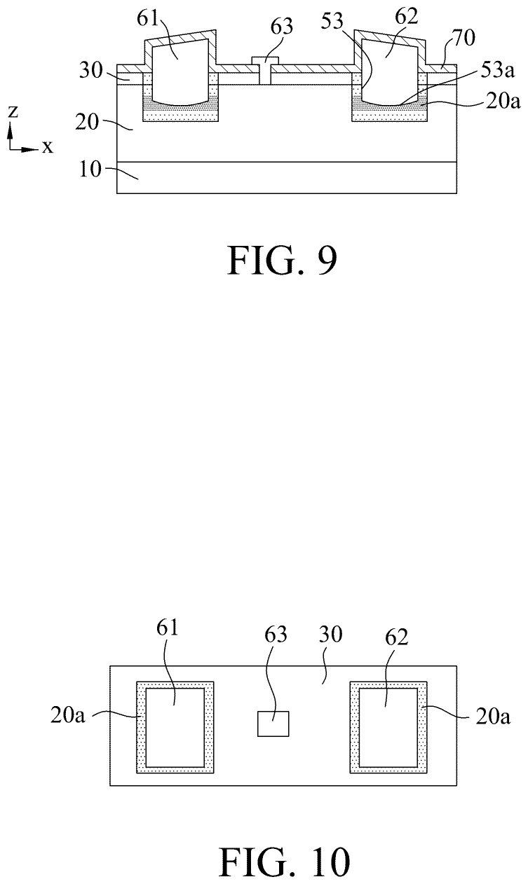

In some embodiments, an ion concentration of each of the ion implantation regions 20a first increases and then decreases in the direction (Z) from the top surface of the epitaxial structure 20 to the substrate 10, and each of the ion implantation regions 20a has a high concentration region. Each of trenches 53 extends into the high concentration region of a respective one of the ion implantation regions 20a. An ion concentration in the high concentration region exceeds a predetermined value, and the predetermined value in each of the ion implantation regions 20a is no smaller than 80% of a concentration peak value of the ions in the each of the ion implantation regions 20a. That is to say, each of the trenches 53 is located in the high concentration region of the respective ion implantation region 20a, in which the ion concentration is no smaller than 80% of the concentration peak value of the ions in the respective ion implantation region 20a. In this embodiment, the ion concentration in the high concentration region of each of the ion implantation regions 20a is greater than 85% of the concentration peak value of the ions in the each of the ion implantation regions 20a. The concentration peak value of the ions in each of the ion implantation regions 20a refers to a greatest concentration value of the ions in the each of the ion implantation regions 20a. Referring to FIGS. 7 to 9, in each of the ion implantation regions 20a, areas having a greater density of dots represent areas of higher concentration of the ions. The bottom surface 53a of each of the trenches 53 is located in the respective ion implantation region 20a having the high concentration region of the ions.

By virtue of the limitations set forth regarding the implantation energy of the ions and the ion concentration, each of the ion implantation regions 20a having the high concentration region of the ions in the epitaxial structure 20 may be formed more easily, thereby lowering a requirement of etching precision and a level of etching difficulty, so that an etching depth does not need to reach a peak depth to ensure a contact between each of the metal layers and a respective one of the ion implantation regions 20a having the high concentration region of the ions. Therefore, ohmic contact resistance may be reduced.

It should be noted that, the implantation energy of the ions and the ion concentration depend on doping depth and doping amount, and are not limited herein.

In some embodiments, a distance between the top surface of the epitaxial structure 20 adjacent to the passivation dielectric layer 30 and a location of the concentration peak value (i.e., where a greatest ion concentration occurs in each of the ion implantation regions 20a) ranges from 10 nm to 50 nm, so that the location of the concentration peak value may be in the GaN layer 21, in the barrier layer 22, or between the GaN layer 21 and the barrier layer 22. For example, when a thickness of the barrier layer 22 ranges from 10 nm to 30 nm, a depth of the location of the concentration peak value may be controlled to exceed the thickness of the barrier layer 22 by using an ion implantation process. For example, when the thickness of the barrier layer 22 is 10 nm, the depth of the location of the concentration peak value is 13 nm. That is to say, the location of the concentration peak value is 13 nm downward of the top surface of the epitaxial structure 20 in the direction (Z) toward the substrate 10. In another example, when the thickness of the barrier layer 22 is 20 nm, the depth of the location of the concentration peak value is 25 nm. When the thickness of the barrier layer 22 is 25 nm, the depth of the location of the concentration peak value is 32 nm. An exact depth of the location of the concentration peak value may depend on actual requirements of the HEMT device, and is not limited herein. By virtue of ensuring the location of the concentration peak value being within the GaN layer 21, a contact between each of the metal layers to be subsequently made and the GaN layer 21 may be ensured, thereby reducing the ohmic contact resistance.

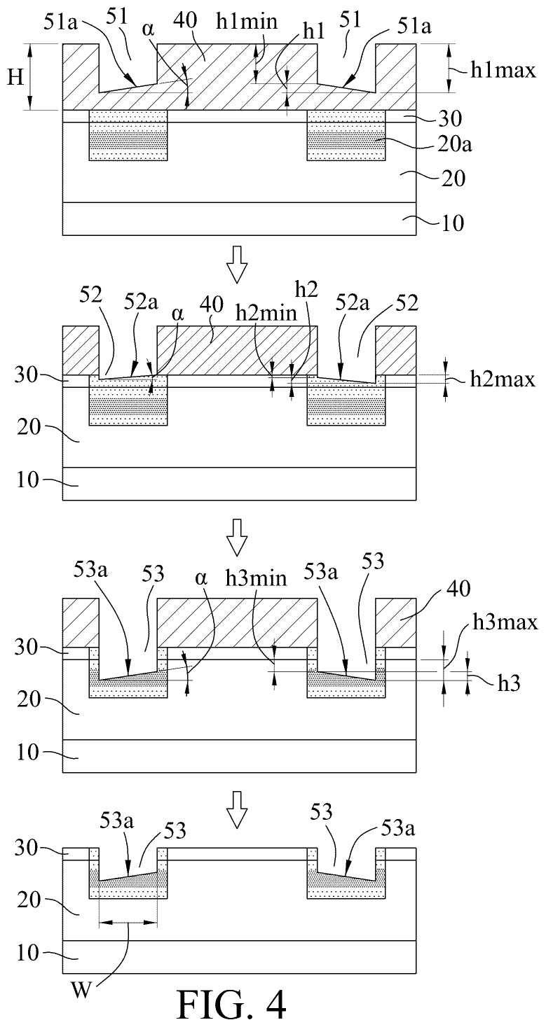

Referring to FIGS. 4 to 6, in step S50, each of the trenches 53 is formed in the ion implantation regions 20a, respectively. Each of the trenches 53 at least extends into the epitaxial structure 20. An area of a bottom surface 53a of each of the trenches 53 is greater than an area of a projection of the bottom surface 53a of the each of the trenches 53 on the substrate 10. An area of a projection of each of the ion implantation regions 20a on the substrate 10 is greater than the area of the projection of the bottom surface 53a of a respective one of the trenches 53 on the substrate 10.

By virtue of the limitations set forth regarding the ion implantation regions 20a and the trenches 53, the requirement of etching precision and the level of etching difficulty is lowered, thereby preventing differences in the etching depths caused by implantation of the ions of different batches, so as to ensure uniformity the ohmic contact resistance.

In some embodiment, the step of forming the trenches 53 includes a step S51. In step S51, a photoresist layer 40 is formed on the passivation dielectric layer 30, and the photoresist layer 40 is patterned to form first preformed trenches 51 located respectively above the ion implantation regions 20a. When patterning the photoresist layer 40, variations in exposure energy and exposure dose may be utilized to achieve different patterns.

An area of a bottom surface 51a of each of the first preformed trenches 51 is greater than an area of a projection of the bottom surface 51a of the each of the first preformed trenches 51 on the substrate 10. The bottom surface 51a of each of the first preformed trenches 51 may not be a flat surface or a completely flat surface in a horizontal direction (X). A specific shape of the bottom surface 51a of each of the first preformed trenches 51 may be designed according to actual requirements. For example, the bottom surface 51a of each of the first preformed trenches 51 may be an inclined flat surface, a curved surface, a concave surface, a convex surface, or combinations thereof. When the bottom surface 51a of each of the first preformed trenches 51 is the inclined flat surface, the bottom surface 51a forms an angle (a) with an imaginary plane that is parallel to the substrate 10, and the angle (a) ranges from 5° to 10°, thereby ensuring a bottom surface 52a of a respective one of second preformed trenches 52 and the bottom surface 53a of a respective one of the trenches 53 may also be etched in such an angle range. In such way, the inclined flat surface of the bottom surface 53a of each of the trenches 53 may be formed to expose the high concentration region of ions in the respective ion implantation region 20a so as to reduce the ohmic contact resistance.

In some embodiments, referring to FIGS. 4 to 6, a maximum depth of each of the first preform trenches 51 extending along a thickness direction of the epitaxial structure 20 is represented by h1max, a minimum depth of each of the first preform trenches 51 extending along the thickness direction of the epitaxial structure 20 is represented by h1 min, and a difference between the maximum depth and the minimum depth of the first preformed trench 51 is represented by h1 that ranges from 44 nm to 225 nm. For example, h1 may be 50 nm, 100 nm, 120 nm, 150 nm, or 200 nm. It should be noted that, in this embodiment, the thickness direction of the epitaxial structure 20 is the direction from the top surface of the epitaxial structure 20 to the substrate 10, and is represented by an arrow Z in the figures. Due to the bottom surface 51a of each of the first preformed trenches 51 being not a completely horizontal surface, the first preformed trench 51 has the maximum depth h1max and the minimum depth h1 min. The maximum depth h1max of each of the first preformed trenches 51 measures from a surface of the photoresist layer 40 away from the passivation dielectric layer 30 to a deepest location of the bottom surface 51a of the each of the first preformed trenches 51. The minimum depth h1 min of each of the first preformed trenches 51 measures from the surface of the photoresist layer 40 away from the passivation dielectric layer 30 to a shallowest location of the bottom surface 51a of the each of the first preformed trenches 51. By virtue of the abovementioned limitations set forth regarding the h1, subsequent etchings of the second preformed trenches 52 and the trenches 53 are facilitated, thereby avoiding a higher ohmic contact resistance caused by the h1 being too great or too small.

In some embodiment, referring to FIGS. 4 to 6, the photoresist layer 40 has a thickness represented by H, and H≥5×h1, thereby ensuring the photoresist layer 40 has enough thickness to be patterned. For example, the thickness (H) of the photoresist layer 40 may range from 1 μm to 2 μm. In this embodiment, each of the first preformed trenches 51 may be or may not be etched to extend to a surface of the passivation dielectric layer 30 to the greatest extent. That is to say, the maximum depth h1max of each of the first preformed trenches 51 may be no greater than the thickness (H) of the photoresist layer 40.

In step S52, the passivation dielectric layer 30 is etched below the first preformed trenches 51 to form the second preformed trenches 52. The passivation dielectric layer 30 may be made of SiN, and may be etched by using an F-based (fluorine-based) gas. An etch selectivity ratio of the photoresist layer 40 to the passivation dielectric layer 30 is 3:1.

In some embodiments, an area of a bottom surface 52a of each of the second preformed trenches 52 is greater than an area of a projection of the bottom surface 52a of the each of the second preformed trenches 52 on the substrate 10. In this embodiment, a shape of the bottom surface 52a of each of the second preformed trenches 52 is the same as that of the bottom surface 51a of a respective one of the first preformed trenches 51. That is to say, by virtue of the patterned photoresist layer 40, the bottom surface 52a of each of the second preformed trenches 52 is formed and has the same shape as that of the bottom surface 51a of each of the first preformed trenches 51. Referring further to FIGS. 4 to 6, the bottom surface 52a of each of the second preformed trenches 52 is an inclined flat surface, a curved surface, a concave surface, a convex surface, or combinations thereof.

Furthermore, a difference between a maximum depth and a minimum depth of each of the second preformed trenches 52 is represented by h2, and h1 and h2 satisfy an equation of h2=h1/A, where A is the value of the etch selectivity ratio of the passivation dielectric layer 30 to the photoresist layer 40 and ranges from 2.5 to 4. That is to say, h2 in each of the second preformed trenches 52 depends on an etching rate of the passivation dielectric layer 30 and the shape of the bottom surface 51a of a respective one of the first preformed trenches 51; specific coefficients of the etching rate of the passivation dielectric layer 30 may depend on actual requirements. It should be noted that each of the second preformed trenches 52 has a maximum depth h2max and a minimum depth h2 min, where the maximum depth h2max measures from a surface of the passivation dielectric layer 30 away from the epitaxial structure 20 to a deepest location of the bottom surface 52a of the each of the second preformed trenches 52. The minimum depth h2 min of each of the second preformed trenches 52 measures from the surface of the passivation dielectric layer 30 away from the epitaxial structure 20 to a shallowest location of the bottom surface 52a of the each of the second preformed trenches 52. A difference (h2) between h2max and h2 min is the difference between the maximum depth and a minimum depth of each of the second preformed trenches 52. By virtue of the abovementioned limitations set forth regarding the h2, a subsequent etching of the trenches 53 is facilitated, thereby avoiding a higher ohmic contact resistance caused by the h2 being too great or too small.

In step S53, the epitaxial structure 20 below the second preformed trenches 52 is etched to form the trenches 53. The area of the bottom surface 53a of each of the trenches 53 is greater than the area of the projection of the bottom surface 53a of the each of the trenches 53 on the substrate 10. That is to say, the bottom surface 53a of each of the trenches 53 may not be a horizontal surface or a completely horizontal surface. A specific shape of the bottom surface 53a of each of the trenches 53 may designed according to actual requirements or based on the shape of the bottom surface 51a of a respective one of the first preformed trenches 51 and/or the bottom surface 52a of a respective one of the second preformed trenches 52. Specifically, after forming the first preformed trenches 51 in the photoresist layer 40, the second preformed trenches 52 and the trenches 53 are formed by respectively etching of the passivation dielectric layer 30 and the epitaxial structure 20. The bottom surface 52a of each of the second preformed trenches 52 and the bottom surfaces 53a of each of the trenches 53 have the same shape as the bottom surface 51a of a respective one of the first preformed trenches 51.

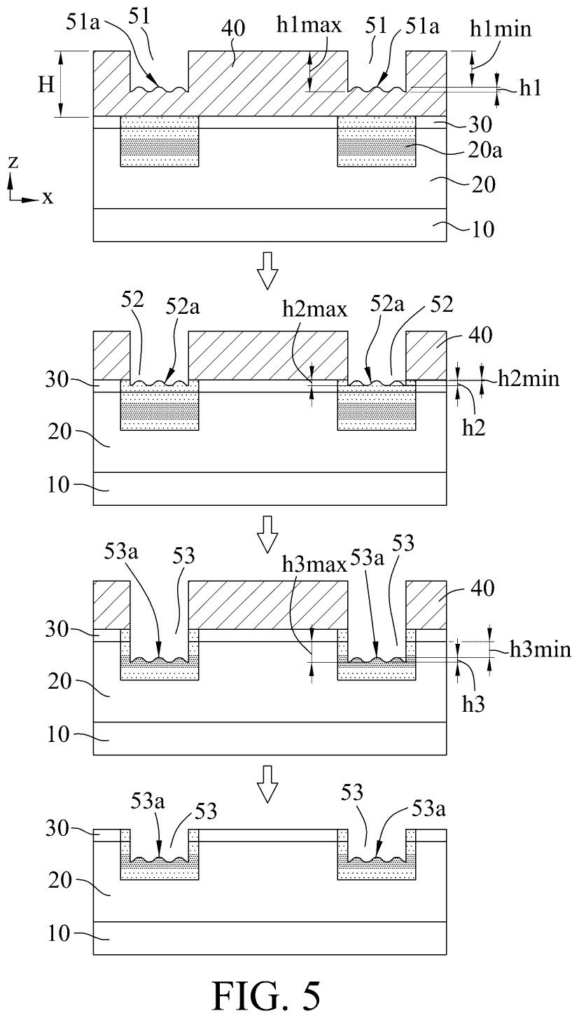

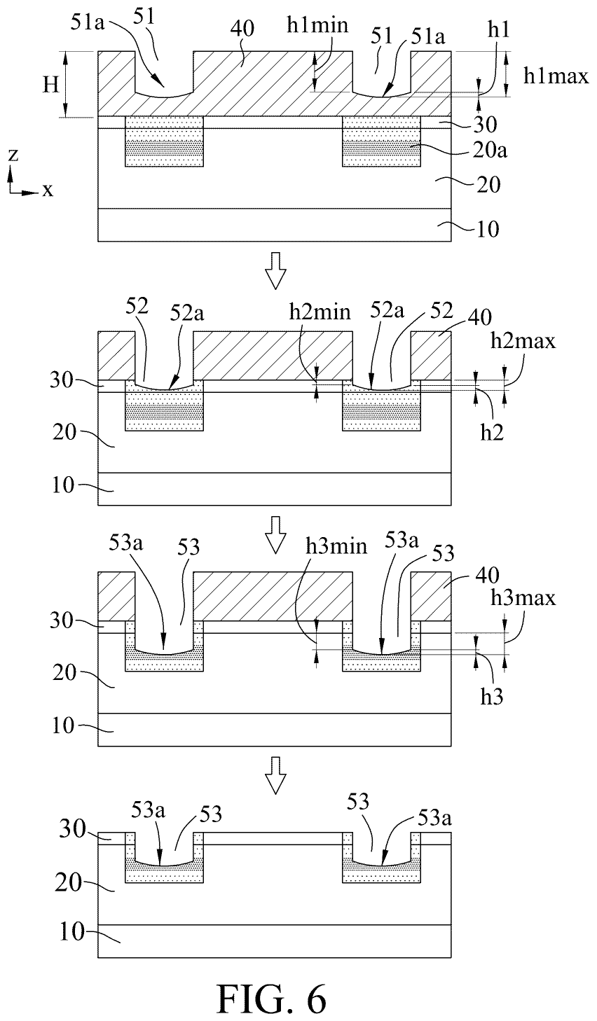

For example, the bottom surface 53a of each of the trenches 53 may be an inclined flat surface, a curved surface, a concave surface, a convex surface, or combinations thereof. Referring to FIG. 4, the bottom surface 53a of each of the trenches 53 is the inclined flat surface. Referring to FIG. 5, the bottom surface 53a of each of the trenches 53 is a combination of the concave surface and the convex surface. Referring to FIG. 6, the bottom surface 53a of each of the trenches 53 is the curved surface. Referring to FIG. 4, when the bottom surface 53a of each of the trenches 53 is the inclined flat surface, the bottom surface 53a forms an angle (α) with an imaginary plane that is parallel to the substrate 10, and the angle (α) ranges from 5° to 10°. In some specific embodiments, the angle (α) is 5°, 7.5°, 9°, etc. In such way, the inclined flat surface of the bottom surface 53a of each of the trenches 53 is completely in a high concentration region of ions in a respective one of the ion implantation regions 20a. As, such, the ohmic contact resistance between each of the metal layers and a respective one of the ion implantation regions 20a may be reduced. When the angle (α) is greater than 10°, each of the metal layers does not contact the high concentration region of the ions in the respective ion implantation region 20a. When the angle (α) is smaller than 5°, a level of the etching precision is increased.

In some embodiments, referring again to FIGS. 4 to 6, a difference between a maximum depth and a minimum depth of the trench 53 is represented by h3, and h1 and h3 satisfy an equation of h3=h1+ (A×B), where A is the value of the etch selectivity ratio of the passivation dielectric layer 30 to the photoresist layer 40 and ranges from 2.5 to 4, and B is a value of an etch selectivity ratio of the passivation dielectric layer 30 to the epitaxial structure 20 and ranges from 1.2 to 2. It should be noted that each of the trenches 53 has a maximum depth h3max and a minimum depth h3 min, where the maximum depth h3max measures from the top surface of the epitaxial structure 20 adjacent to the passivation dielectric layer 30 to a deepest location of the bottom surface 53a of the each of the trenches 53. The minimum depth h3 min of each of the trenches 53 measures from the top surface of the epitaxial structure 20 adjacent to the passivation dielectric layer 30 to a shallowest location of the bottom surface 53a of the each of the trenches 53. A difference h3 between h3max and h3 min is the difference between the maximum depth h3max and the minimum depth h3 min of each of the trenches 53. By virtue of the abovementioned limitations set forth regarding the h3, a contact between each of the metal layers and a respective one of the ion implantation regions is ensured, thereby avoiding a higher ohmic contact resistance caused by the h3 being too great or too small.

In some embodiments, the difference h3 between the maximum depth h3max and the minimum depth h3 min of each of the trenches 53 ranges from 10 nm to 50 nm. For example, h3 may be 10 nm, 15 nm, 20 m, 25 nm, 30 nm, 40 nm, or 50 nm. A width of the bottom surface 53a of each of the trenches 53 in the horizontal direction is represented by W that ranges from 10 μm to 50 μm. Referring to FIGS. 4 to 6, the horizontal direction is defined as a direction shown by an arrow X in the figures, and the horizontal direction is perpendicular to the direction from the top surface of the epitaxial structure 20 to the substrate 10 (a direction shown by an arrow (Z). The width (W) of the bottom surface 53a of each of the trenches 53 in the horizontal direction may be adjusted according to the actual requirements. Configuration of the width (W) in the horizontal direction of the bottom surface 53a of a first one of the trenches 53 at the source electrode 61 and the width (W) in the horizontal direction of the bottom surface 53a of a second one of the trenches 53 at the drain electrode 62 may or may not be the same. In some embodiments, the width (W) in the horizontal direction of the bottom surface 53a of the second one of the trenches 53 at the drain electrode 62 is greater than the width (W) in the horizontal direction of the bottom surface 53a of the first one of the trenches 53 at the source electrode 61.

When the epitaxial structure 20 at least includes the GaN layer 21 and the barrier layer 22 disposed on the GaN layer 21, as an example, referring to FIG. 3, the trenches 53 are respectively etched from the second preformed trenches 52 toward the epitaxial structure 20 until the GaN layer 21 is exposed, thereby allowing the metal layers (i.e., the source electrode 61 and the drain electrode 62) that are subsequently formed to directly contact the GaN layer 21, and preventing the trenches 53 from completely penetrating the barrier layer 22. In such way, an ohmic contact between the barrier layer 22 and each of the metal layers is ensured and the ohmic contact resistance is reduced.

Referring to FIGS. 7 to 10, in step S60, each of the metal layers is deposited in a respective one of the trenches 53 so as to form an ohmic contact. Specifically, each of the metal layers, e.g., a Ti/Pt/Au/Ti layered structure, may be deposited by a vapor deposition process without high temperature annealing, thereby avoiding a poor quality of the source electrode 61 and/or the drain electrode 62 caused by the high temperature. The metal layers may be a single layer of metal, a single layer of alloy, a multilayer of metal, or a multilayer of alloy. In this embodiment, the metal layers includes the source electrode 61 and the drain electrode 62, i.e., the source electrode 61 and the drain electrode 62 are formed by the vapor deposition process, where the source electrode 61 and the drain electrode 62 are isolated from each other.

It should be noted that, in this embodiment, the ion implantation region 20a includes a source ion implantation region and a drain ion implantation region. The first one of the trenches 53 is formed in the source ion implantation region. The source electrode 61 is formed in the first one of the trenches 53. The second one of the trenches 53 is formed in the drain ion implantation region. The drain electrode 62 is formed in the second one of the trenches 53.

Each of the source electrode 61 and the drain electrode 62 may be made of nickel, gold, titanium, aluminum, platinum, chromium, alloys thereof, or a layered structure thereof, such as a Ti/Au layered structure, so as to facilitate an ohmic contact with the epitaxial structure 20. Quality of each of the source electrode 61 and the drain electrode 62 formed by the vapor deposition process is better for having a uniform surface and clean edges, thereby improving reliability of the HEMT device and preventing electrical breakdown.

In this embodiment, by virtue of implanting the ions followed by etching, a contact between each of the source electrode 61 and the drain electrode 62 with the high concentration region of the ions in a respective one of the ion implantation regions 20a is ensured, thereby lowering the requirement of etching precision and reducing the ohmic contact resistance.

In some embodiments, the method for manufacturing the HEMT device further includes the following steps.

A gate electrode 63 is formed on the passivation dielectric layer 30. The gate electrode 63 is in electrical contact with the epitaxial structure 20 through a through hole of the passivation dielectric layer 30. The gate electrode 63 may be designed to be T-shaped or notch-shaped so as to effectively reduce a short channel effect of the HEMT device. Specific structure of the gate electrode 63 is not limited to descriptions herein. The gate electrode 63 may be made of Ni, Ag, Cu, Co, Pu, Ni, Pt, Au, alloys thereof, or a layered structure thereof, and is generally formed by using methods such as electroplating, electron beam evaporation, or sputtering. For forming a Schottky contact between the gate electrode 63 and the epitaxial structure 20, an annealing process is not necessary, and the Schottky contact may be formed after the gate electrode 63 is formed.

A passivation protection layer 70 is formed on the passivation dielectric layer 30 to protect the gate electrode 63, the drain electrode 62, and the source electrode 61. The passivation protection layer 70 may be made of SiN so as to serve as a water vapor barrier and protect the HEMT device. According to actual requirements, other passivation structures may also be formed on the passivation protection layer 70. It should be noted that a step of removing the photoresist layer 40 is performed before forming of the gate electrode 63, i.e., an organic solution may be used to remove the photoresist layer 40 before forming of the metal layers.

By virtue of the above-mentioned method for manufacturing the HEMT device, an area of ohmic contact may be increased, the ohmic contact resistance is reduced, and the requirement of etching precision and the level of etching depth is lowered. The HEMT device of the disclosure is highly adaptable. Even if implantation conditions change, the metal layers may still be in contact with the high concentration region of the ions in the respective ion implantation region 20a, thereby preventing differences in the etching depths caused by implantation of the ions of different batches, so as to ensure uniformity in the method and improve performance of the HEMT device.

Referring to FIGS. 7 to 9, the HEMT device according to another embodiment of the disclosure is provided. According to this embodiment, the HEMT device includes a substrate 10, an epitaxial structure 20, ion implantation regions 20a, trenches 53, and metal layers.

The epitaxial structure 20 is disposed on the substrate 10. The substrate 10 may be a substrate known to those skilled in the art adapted for disposing semiconductor integrated circuit elements thereon, such as silicon, silicon carbide, sapphire, gallium nitride, and the like. The epitaxial structure 20 includes at least a GaN layer 21 that is disposed on the substrate 10 and a barrier layer 22 that is disposed on the GaN layer 21. A heterojunction interface is formed between the GaN layer 21 and the barrier layer 22 for generating a two-dimensional electron gas. The barrier layer 22 may be a single layered structure or a multilayered structure made of aluminum gallium nitride, aluminum nitride, aluminum indium nitride, indium gallium nitride, or aluminum indium gallium nitride. According to actual requirements, the epitaxial structure 20 may further include a nucleation layer, a transition layer, a buffer layer, an insertion layer, or combinations thereof (not shown in the figures), and is not limited thereto.

The passivation dielectric layer 30 is disposed on the epitaxial structure 20 for electrical isolation. The passivation dielectric layer 30 may be made of SiO₂, SiN, Al₂O₃, SiON, or combinations thereof, and is not limited thereto.

Each of the ion implantation regions 20a extends in a direction (Z) from a top surface of the epitaxial structure 20 to the substrate 10. Ions that are implanted may be silicon ions. The ions may be implanted perpendicularly onto the top surface of the epitaxial structure 20, or at an angle according to actual requirements and are not limited thereto. When implanting the ions into the ion implantation regions 20a, implantation energy goes from high to low. That is to say, a high energy is used first to implant the ions, followed by a low energy to implant the ions. Specifically, the high energy used to implant the ions allows a concentration of the ions to be greater and a distribution of the ions to be deeper. In order to prevent the ions that implanted by the high energy from being blocked by the ions implanted by the low energy, the high energy is used first, so as to achieve a predetermined depth of implantation for the ion implantation regions 20a.

Each of the trenches 53 is disposed in a respective one of the ion implantation regions 20a and extends in the direction (Z) from the top surface of the epitaxial structure 20 to the substrate 10. Each of the trenches 53 extends at least into a portion of the epitaxial structure 20. In some embodiments, each of the trenches 53 extends in the direction (Z) from the top surface of the epitaxial structure 20 to the GaN layer 21.

An area of a bottom surface 53a of each of the trenches 53 is greater than an area of a projection of the bottom surface 53a of the each of the trenches 53 on the substrate 10. The bottom surface 53a of the trench 53 may not be a flat surface or a completely flat surface in a horizontal direction (X). A specific shape of the bottom surface 53a of each of the trenches 53 may be designed according to actual requirements. For example, the bottom surface 53a of each of the trenches 53 may be an inclined flat surface, a curved surface, a concave surface, a convex surface, or combinations thereof. When the bottom surface 53a of each of the trenches 53 is the inclined flat surface, the bottom surface 53a forms an angle (α) with an imaginary plane that is parallel to the substrate 10, and the angle (α) ranges from 5° to 10°. Ion concentration is higher in such angle range, thereby ensuring the bottom surface 53a of each of the trenches 53 may be formed to expose a high concentration region of the ions in a respective one of the ion implantation regions 20a, so as to reduce ohmic contact resistance.

Furthermore, a projection of each of the ion implantation regions 20a on the substrate 10 is greater than the projection of the bottom surface 53a of a respective one of the trenches 53 on the substrate 10, so as to ensure each of the metal layers disposed in a respective one of the trenches 53 may effectively contact a respective one of the ion implantation regions 20a, thereby preventing differences in etching depths caused by implantation of the ions of different batches, so as to ensure uniformity of ohmic contact.

A difference between a maximum depth and a minimum depth of each of the trenches 53 is represented by h3 that ranges from 10 nm to 50 nm. A width of the bottom surface 53a of the trench 53 in the horizontal direction (X) is represented by W that ranges from 10 μm to 50 μm.

In some embodiments, the bottom surface 53a of each of the trenches 53 contacts the high concentration region of the ions in the respective ion implantation region 20a. That is to say, the bottom surface 53a of each of the trenches 53 is in the high concentration region of the ions in the respective ion implantation region 20a. Specifically, each of the ion implantation regions 20a has the high concentration region, and the ion concentration in the high concentration region exceeds a predetermined value. The predetermined value in each of the ion implantation regions 20a is no smaller than 80% of a concentration peak value of the ions in the each of the ion implantation regions 20a. By virtue of the bottom surface 53a of each of the trenches 53 being in the high concentration region of the ions in the respective ion implantation region 20a, a contact between each of the metal layers and the high concentration region in the respective ion implantation region 20a is ensured, thereby reducing the ohmic contact resistance. In some embodiments, a distance between the top surface of the epitaxial structure 20 adjacent to the passivation dielectric layer 30 and a location of the concentration peak value (i.e., where a greatest ion concentration occurs in each of the ion implantation regions 20a) ranges from 10 nm to 50 nm, so that the location of the concentration peak value may be in the GaN layer 21, in the barrier layer 22, or between the GaN layer 21 and the barrier layer 22.

Referring to FIG. 10, each of the metal layers is disposed in a respective one of the trenches 53, thereby forming an ohmic contact. In some embodiments, the metal layers includes a source electrode 61 and a drain electrode 62. The source electrode 61 and the drain electrode 62 are formed by a vapor deposition process, where the source electrode 61 and the drain electrode 62 are isolated from each other. It should be noted that, the ion implantation regions 20a includes a source ion implantation region and a drain ion implantation region that are spaced apart from each other. A first one of the trenches 53 is formed in the source ion implantation region. The source electrode 61 is formed in the first one of the trenches 53. A second one of the trenches 53 is formed in the drain ion implantation region. The drain electrode 62 is formed in the second one of the trenches 53.

It should be noted that the ion concentration, implantation energy, and implantation depth in the source ion implantation region and the drain ion implantation region may be the same or different. The structure and size of the first one of the trenches 53 in the source ion implantation region and the second one of the trenches 53 in the drain ion implantation region may be the same or different. The structure, size, and material of the source electrode 61 and the drain electrode 62 may be the same or different, all of which are depended on actual requirements, and are not limited herein.

Each of the source electrode 61 and the drain electrode 62 may be made of nickel, gold, titanium, aluminum, platinum, chromium, alloys thereof, or a layered structure thereof, such as a Ti/Au layered structure, so as to facilitate an ohmic contact with the epitaxial structure 20. Quality of each of the source electrode 61 and the drain electrode 62 formed by the vapor deposition process are better for having a uniform surface and clean edges, thereby improving reliability of the HEMT device and preventing electrical breakdown.

In an embodiment, the HEMT device further includes a gate electrode 63 and a passivation protection layer 70. The gate electrode 63 is formed on the passivation dielectric layer 30, and is in electrical contact with the epitaxial structure 20 through a through hole of the passivation dielectric layer 30. The gate electrode 63 may be designed to be T-shaped or notch-shaped so as to effectively reduce a short channel effect of the HEMT device. Specific structure of the gate electrode 63 is not limited to descriptions herein. The passivation protection layer 70 is disposed on the passivation dielectric layer 30 so as to serve as a water vapor barrier and protect the HEMT device.

It should be noted that the present embodiment may be described with reference to the foregoing embodiment with respect to the method for manufacturing the HEMT device, and other structures and functions will not be repeated herein.

In summary, in the HEMT device and the method for manufacturing the same provided by this embodiment of the present disclosure, by virtue of the ion implantation and etching of the trenches, an area of ohmic contact is increased. By virtue of increasing the area of the bottom surface 53a of each of the trenches 53, a contact area of a respective one of the metal layers and the high concentration region of the ions in a respective one of the ion implantation regions 20a is increased, thereby reducing the ohmic contact resistance. In addition, a requirement of etching precision and etching depth is lowered. Even if implantation conditions change, each of the metal layers may still be in contact with the high concentration region of the ions in the respective one of the ion implantation regions 20a, thereby preventing differences in the etching depths caused by implantation of the ions of different batches, so as to ensure uniformity in the method and improve performance of the HEMT device.

The disclosure further provides a radio frequency (RF) module that includes the HEMT device. The RF module may be used in base stations, cellphones, and other communication terminal devices. The HEMT device is a gallium nitride-based HEMT device, which is the same as those described in the previous embodiments, and details thereof will not be repeated herein.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for manufacturing a high electron mobility transistor (HEMT) device, comprising steps of:
providing a substrate;
forming an epitaxial structure on the substrate;
forming a passivation dielectric layer on the epitaxial structure;
implanting ions in a direction from a top surface of the epitaxial structure to the substrate so as to form an ion implantation region;
forming a trench in the ion implantation region, the trench at least extending into the epitaxial structure, an area of a bottom surface of the trench being greater than an area of a projection of the bottom surface of the trench on the substrate, an area of a projection of the ion implantation region on the substrate being greater than the area of the projection of the bottom surface of the trench on the substrate; and
depositing a metal layer in the trench so as to form an ohmic contact.

2. The method as claimed in claim 1, wherein forming the trench includes:
forming a photoresist layer on the passivation dielectric layer, and patterning the photoresist layer to form a first preformed trench located above the ion implantation region;
etching the passivation dielectric layer below the first preformed trench to form a second preformed trench; and
etching the epitaxial structure below the second preformed trench to form the trench.

3. The method as claimed in claim 2, wherein
a difference between a maximum depth and a minimum depth of the first preformed trench is represented by h1 that ranges from 44 nm to 225 nm, the photoresist layer has a thickness represented by H, and
h1 and H satisfy an equation of H≥5×h1.

4. The method as claimed in claim 2, wherein
a difference between a maximum depth and a minimum depth of the first preformed trench is represented by h1,
a difference between a maximum depth and a minimum depth of the second preformed trench is represented by h2, and
h1 and h2 satisfy an equation of h2=h1/A, where A is a value of an etch selectivity ratio of the passivation dielectric layer to the photoresist layer and ranges from 2.5 to 4.

5. The method as claimed in claim 2, wherein
a difference between a maximum depth and a minimum depth of the first preformed trench is represented by h1,
a difference between a maximum depth and a minimum depth of the trench is represented by h3, and
h1 and h3 satisfy an equation of h3=h1÷(A×B), where A is a value of an etch selectivity ratio of the passivation dielectric layer to the photoresist layer and ranges from 2.5 to 4, and B is a value of an etch selectivity ratio of the passivation dielectric layer to the epitaxial structure and ranges from 1.2 to 2.

6. The method as claimed in claim 1, wherein a difference between a maximum depth and a minimum depth of the trench is represented by h3 that ranges from 10 nm to 50 nm.

7. The method as claimed in claim 1, wherein the epitaxial structure at least includes a GaN layer that is disposed on the substrate and a barrier layer that is disposed on the GaN layer, the trench being formed by etching the epitaxial structure until the GaN layer is exposed.

8. The method as claimed in claim 1, wherein an ion concentration of the ion implantation region first increases and then decreases in a direction from the top surface of the epitaxial structure to the substrate, the ion implantation region having a high concentration region, an ion concentration in the high concentration region exceeding a predetermined value, the trench extending into the high concentration region, the predetermined value being no smaller than 80% of a concentration peak value of the ions in the ion implantation region.

9. The method as claimed in claim 2, wherein the bottom surface of the trench, a bottom surface of the first preformed trench, and a bottom surface of the second preformed trench are each an inclined flat surface, a curved surface, a concave surface, a convex surface, or combinations thereof.

10. An HEMT device, comprising:
a substrate;
an epitaxial structure disposed on said substrate;
a passivation dielectric layer disposed on said epitaxial structure;
an ion implantation region extending in a direction from a top surface of said epitaxial structure to said substrate;
a trench located in said ion implantation region, and extending in the direction to reach at least a portion of said epitaxial structure, an area of said bottom surface of said trench being greater than an area of a projection of said bottom surface of said trench on said substrate, an area of a projection of said ion implantation region on said substrate being greater than said area of said projection of said bottom surface of said trench on said substrate; and
a metal layer disposed in said trench so as to form an ohmic contact.

11. The HEMT device as claimed in claim 10, wherein said epitaxial structure at least includes a GaN layer that is disposed on said substrate and a barrier layer that is disposed on said GaN layer.

12. The HEMT device as claimed in claim 11, wherein said trenches extends in the direction to reach said GaN layer.

13. The HEMT device as claimed in claim 12, wherein an ion concentration of said ion implantation region first increases and then decreases in the direction from said top surface of said epitaxial structure to said substrate.

14. The HEMT device as claimed in claim 10, wherein said ion implantation region has a high concentration region, an ion concentration in said high concentration region exceeding a predetermined value, the predetermined value being no smaller than 80% of a concentration peak value of ions in said ion implantation region, said bottom surface of said trench being formed in said high concentration region.

15. The HEMT device as claimed in claim 10, wherein a difference between a maximum depth and a minimum depth of said trench is represented by h3 that ranges from 10 nm to 50 nm.

16. The HEMT device as claimed in claim 10, wherein said bottom surface of said trench is an inclined flat surface, a curved surface, a concave surface, a convex surface, or combinations thereof.

17. The HEMT device as claimed in claim 16, wherein when said bottom surface of said trench is said inclined flat surface, said bottom surface of said trench forming an angle with an imaginary plane that is parallel to said substrate, said angle ranging from 5° to 10°.

18. The HEMT device as claimed in claim 11, wherein an aluminum nitride insertion layer is disposed between said GaN layer and said barrier layer.

19. The HEMT device as claimed in claim 11, wherein a thickness of said barrier layer ranges from 10 nm to 30 nm.

20. A radio frequency module, comprising the HEMT device as claimed in claim 10.
